(19) United States
(12) Patent Application Publication
(10) Pub. No.: US 2007/0044003 A1
(43) Pub. Date: Feb. 22, 2007

(54) Method and apparatus of detecting and correcting soft error

(76) Inventors: Jack Doweck, Haifa (IL); Ittai Anati, Haifa (IL); Tsafrir Israeli, Yokneam Ilit (IL)

Correspondence Address: PEARL COHEN ZEDEK LATZER, LLP, 1500 BROADWAY, 12TH FLOOR, NEW YORK, NY, 10036, US

(21) Appl. No.: 11/196,289

(22) Filed: Aug. 4, 2005

(51) Int. Cl. G11C 29/00

(52) U.S. Cl. 714/763

(57) ABSTRACT

Briefly, a method and apparatus of detecting and correcting soft error in a way of a ways group of a cache bank The detection of the soft error may be done by comparing between two replicas of the ways groups. The correction may be done by copying data from one replica of the ways group to another replica of the way group.

### BACKGROUND OF THE INVENTION

Soft error is a term that is used to describe random corruption of data in computer memory. Such corruption may be caused, for example, by particles in normal environmental radiation. More specifically, for example, alpha particles may cause bits in electronic data to randomly “flip” in value, introducing the possibility of error into the data.

Modern computer processors tend to have increasingly large caches, and consequently, an increased probability of encountering soft errors. In some methods of handling soft errors in caches, efforts have been made to devise invested made to recover from soft errors without shutting down the processor. One such known method uses Error Correction Code (ECC). ECC may be implemented by additional hardware logic built into a cache; the logic is intended to detect soft errors and execute a hardware algorithm to correct some of the soft errors. For example a certain ECC implementation is able to detect errors in two bits but correct a single bit error. However, one disadvantage of ECC may be that the additional hardware takes up space on the silicon chip and requires time to perform the needed computations, imposing further area and timing constraints on the overall design. This disadvantage has a negative impact, particularly in Level 1 caches where low latency and small area of the processor are of capital importance.

Moreover, an additional cycle may need to be added to the cache access time in order to accommodate the ECC's soft error correction logic, adversely impacting processor performance even when no soft errors are detected. Another complication may be when the cache includes partial write capability of variable length and/or misaligned address. In such caches, for example, a write that may not exactly overlap a “word” on which the ECC is computed, the cache may need to read that “word”, merge the partial write, and only then compute the new ECC.

### BRIEF DESCRIPTION OF TIE DRAWINGS

The subject matter regarded as the invention is particularly pointed out and distinctly claimed in the concluding portion of the specification. The invention, however, both as to organization and method of operation, together with objects, features and advantages thereof, may best be understood by reference to the following detailed description when read with the accompanied drawings in which:

FIG. 1 is a schematic illustration of a computer system according to some exemplary embodiment of the present invention;

FIG. 2 is a schematic illustration of a portion of a cache according to some exemplary embodiments of the present invention; and

FIG. 3 is an illustration of a schematic block diagram of a read data path and parity calculation of a cache according to an exemplary embodiment of the present invention.

It will be appreciated that for simplicity and clarity of illustration, elements shown in the figures have not necessarily been drawn to scale. For example, the dimensions of some of the elements may be exaggerated relative to other elements for clarity. Further, where considered appropriate, reference numerals may be repeated among the figures to indicate corresponding or analogous elements.

### DETAILED DESCRIPTION OF THE INVENTION

In the following detailed description, numerous specific details are set forth in order to provide a thorough understanding of the invention. However it will be understood by those of ordinary skill in the art that the present invention may be practiced without these specific details. In other instances, well-known methods, procedures, components and circuits have not been described in detail so as not to obscure the present invention.

Some portions of the detailed description, which follow, are presented in terms of algorithms and symbolic representations of operations on data bits or binary digital signals within a computer memory. These algorithmic descriptions and representations may be the techniques used by those skilled in the data processing arts to convey the substance of their work to others skilled in the art.

Unless specifically stated otherwise, as apparent from the following discussions, it is appreciated that throughout the specification discussions utilizing terms such as “processing,” “computing,” “calculating,” “determining,” or the like, refer to the action and/or processes of a computer or computing system, or similar electronic computing device, that manipulate and/or transform data represented as physical, such as electronic, quantities within the computing system's registers and/or memories into other data similarly represented as physical quantities within the computing system's memories, registers or other such information storage, transmission or display devices. In addition, the term “plurality” may be used throughout the specification to describe two or more components, devices, elements, parameters and the like. For example, “plurality of instructions” describes two or instructions.

It should be understood that the present invention may be used in a variety of applications. Although the present invention is not limited in this respect, the circuits and techniques disclosed herein may be used in many apparatuses such as computer systems, processors, CPU or the like. Processors intended to be included within the scope of the present invention include, by way of example only, a reduced instruction set computer (RISC), a processor that have a pipeline, a complex instruction set computer (CISC) and the like.

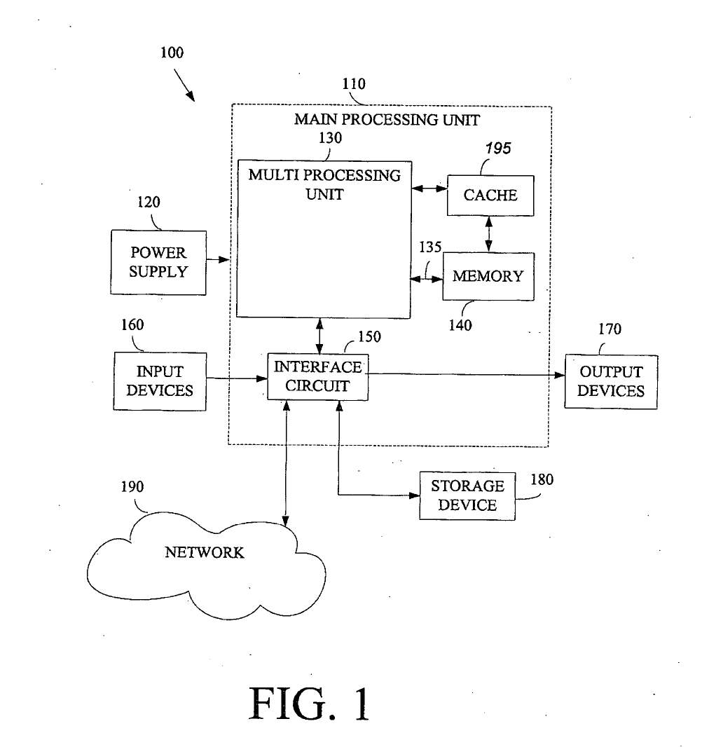

Turning to FIG. 1, a block diagram of a computer system 100 according to an exemplary embodiment of the invention is shown. Although the scope of the present invention is not limited in this respect, computer system 100 may be a personal computer (PC), a server, a personal digital assistant (PDA), an Internet appliance, a cellular telephone, or any other computing device. According to one exemplary embodiment of the invention, computer system 100 may include a main processing unit 110 powered by a power supply 120. According to embodiments of the invention, main processing unit 110 (e.g. addressing server) may include a multi-processing unit 130 electrically coupled by a system interconnect 135 to a memory device 140 and one or more interface circuits 150. For example, system interconnect 135 may be an address/data bus, if desired. It should be understood that interconnects other than busses may be used to connect multi-processing unit 130 to memory device 140. For example, one or more dedicated lines and/or a crossbar may be used to connect multi-processing unit 130 to memory device 140.

According to some embodiments of the invention, multi-processing unit 130 may include any type of processing unit, such as, for example a processor from the Intel® Pentium™ family of microprocessors, the Intel® Itanium™ family of microprocessors, and/or the Intel® XScale™ family of processors. In addition, multi-processing unit 130 may include any type of cache memory, such as, for example, static random access memory (SRAM) and the like. Memory device 140 may include a dynamic random access memory (DRAM), non-volatile memory, or the like. In one example, memory device 140 may store a software program which may be executed by multi-processing unit 130, if desired.

Furthermore, interface circuit(s) 150 may include an Ethernet interface and/or a Universal Serial Bus (USB) interface, a wireless network interface card, a network interface card and/or the like. In some exemplary embodiments of the invention, one or more input devices 160 may be connected to interface circuits 150 for entering data and commands into the main processing unit 110. For example, input devices 160 may include a keyboard, mouse, touch screen, track pad, track ball, isopoint, a voice recognition system, and/or the like.

According to some exemplary embodiments of the invention, main processing unit 110 may include one or more addressing servers. In this exemplary embodiment, the addressing servers may include a plurality of multi-processing units 130. In some other embodiments of the invention, the addressing servers may include one or more memory devices 140 operably coupled to multi-processing units 130, if desired.

Although the scope of the present invention is not limited in this respect, the output devices 170 may be operably coupled to main processing unit 110 via one or more of interface circuits 160 and may include one or more displays, printers, speakers, and/or other output devices, if desired. For example, one of the output devices may be a display. The display may be a cathode ray tube (CRTs), liquid crystal displays (LCDs), or any other type of display.

According to embodiments of the invention, computer system 100 may include one or more storage devices 180. For example, computer system 100 may include one or more hard drives, one or more compact disks (CD) drive, one or more digital versatile disk drives (DVD), and/or other computer media input/output (I/O) devices, if desired.

Furthermore, computer system 100 may exchange data with other devices via a connection to a network 190. The network connection may be any type of network connection, such as an Ethernet connection, digital subscriber line (DSL), telephone line, coaxial cable, etc. Network 190 may be any type of network, such as the Internet, a telephone network, a cable network, a wireless network and/or the like.

Although the scope of the present invention is not limited in this respect, types of memory that may be used with embodiments of the present invention may be, for example, a shift register, a flip flop, a Flash memory, a read access memory (RAM), dynamic RAM (DRAM), static RAM (SRAM) and the like.

According to some exemplary embodiment of the invention, computer system 100 may include a cache 195. Cache 195 may include a level 1 (L1) cache and/or a level 2 (L2) cache, if desired. In some other embodiments of the invention cache 195 may include more than two levels, if desired. In some embodiments, for example, a cache level of cache 195 may include N sets which may be directly addressable by part of the address bits (N>=1). Furthermore, a set of the N sets may be arranged in a plurality of (e.g. two or more) ways to determine the cache 195 associatively. For example cache 195 may include 64 sets wherein a set may include 8 ways, although the scope of the present invention is in no way limited to this example.

According to an exemplary embodiment of the invention, L1 cache may include a mechanism capable of detecting and correcting soft errors in one or more cells of cache 195, if desired. Detecting and correcting soft errors may done by splitting cache 195 into two replicas and comparing bits output from the two replicas. In case of detecting a bit mismatch, a recovery mechanism may be invoked, although the scope of the present invention is not limited to this exemplary embodiment of the invention.

For example, splitting cache 195 may be done by hardware and more specifically by implementing two similar cache arrays. In another exemplary embodiment of the invention, splitting cache 195 may be done by splitting cache 195 into two ways groups, for example, a first ways group may include ways 0-3 and a second ways group may includes ways 4-7. In this example ways 0-3 and ways 4-7 may be written with exactly the same data bits. In some other embodiments of the invention, the concept of replicating and/or splitting the cache may be applied to an array that is not a cache, if desired.

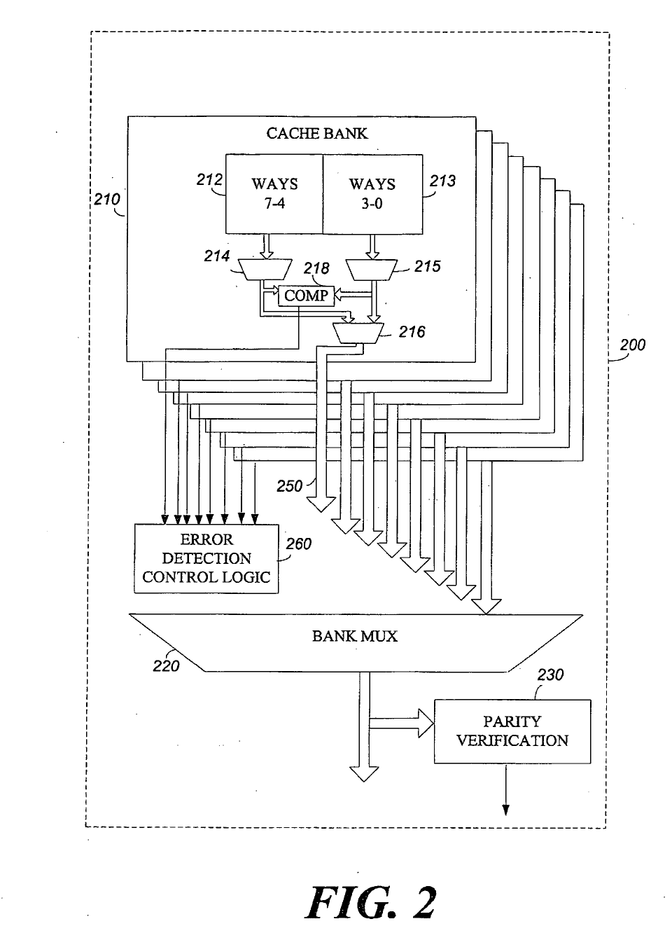

Turning to FIG. 2, an illustration of a portion of a cache 200 according to some exemplary embodiments of the present invention is shown. According to this exemplary embodiment of the invention, cache 200 may include for example, at least a L1 cache. According to this example, the L1 cache of cache 200 may include a plurality of cache banks 210, a multiplexer 220, an error detection control logic 260 and a parity verification block 230. According to some exemplary embodiments of the invention, cache banks 210 may include eight cache banks. Cache banks 210 may have similar architectures, including a ways group 212, a ways group 213, multiplexers 214, 215 and 216, and a comparator 218.

Although the scope of the present invention is not limited in this respect, this exemplary embodiment of the invention may employ the concept of functional redundancy checking (FRC). According to this concept, for example, two processors may perform the same operations wherein one processor may check the operations of the other processor, if desired.

According to embodiments of the invention, the FRC concept may be applied to a task of detecting and correcting soft errors. For example, ways groups 212 may include a copy of data of ways group 213. In order to detect soft errors, the outputs of ways groups 212 and 213 may be compared. In case of a mismatch, a recovery flow may be invoked. Thus, a high probability of both multiple bit error detection and multiple bit error correction may be achieved. The probability of detection and correction may depend on the statistical probability of a soft error hitting the same byte location in both way n and way n+4 over a period of time. In some embodiments of the invention, the four lower ways (e.g. ways 0-3) and the four upper ways (e.g. ways 4-7) may be located in two different physical cache banks (not shown). Locating the four lower ways (e.g. ways 0-3) and the four upper ways (e.g. ways 4-7) in two different physical cache banks may drastically reduce the probability of a soft error hitting the same byte in both a low way and a high way. Thus, a probability of an unrecoverable or undetectable error may be reduced.

According to some embodiments of the invention, cache 200 may be configured to operate in FRC mode. The FRC mode may be enabled or disabled, if desired. When cache 200 may operate in FRC mode, any write to cache 200 writes exactly the same data to the corresponding locations in both ways groups. According to this example, when cache 200 operates in FRC mode multiplexers 214, 215 may provide outputs of ways group 212 and 213, respectively, to multiplexer 216. Multiplexer 216 may allow to feed a data path 250 with the outputs of only one ways group. For example, multiplexer 216 may allow to feed a data path 250 with the outputs of ways group 213 (e.g. ways 0-3).

During a read operation, the outputs of ways group 213 may be compared to the outputs of ways group 212. For example, comparator 218 may compare the outputs of multiplexer 215 to the outputs of multiplexer 214. The results of may be sent to error detection control logic 260. According to some exemplary embodiments of the invention, error detection control logic 260 may perform, for example 8 comparisons from eight cache banks 210. In case of a comparison mismatch, error detection control logic 260 may force a micro-event (e.g. a hardware interrupt) which may cause a correction micro-code assist flow to be invoked. It should be understood that a correction assist may be implemented by hardware, by software or by any combination of hardware and software.

According to exemplary embodiments of the invention, for example, a soft error may modify a way line of one of way groups 212, 213. Thus, ways group 212 may be different from ways group 213. Comparing ways groups 212, 213 may cause the comparison mismatch. The correction micro-code assist flow may operate as follows. If the way line is not modified, the micro-code assist flow may invalidate the way line and reissue the load. The reissued load will retrieve data from the next cache level or memory (for example, from an ECC protected L2 cache, if desired). However, if the way line has been modified, the micro-code assist flow may extract the data from the corresponding ways group 212 (e.g., ways 4-7) and update ways group 213 (e.g. ways 0-3) with the corrected data. For example, the correction of the ways may be done using a micro-code that performs direct read to ways group 212 and direct writes to a specific way of ways group 213, if desired. Parity verification block 230 may perform parity verification during the read of ways 4-7, if desired. It should be understood that some errors may be unrecoverable. For example, a parity error in ways group 4-7 during the error correction flow may result an unrecoverable error.

Although the method and the architecture of detecting and correcting soft error in ways have been describe with reference to one cache bank, it should be understood that the method may be performed with one or more cache banks alone or in combination with other cache banks. According to embodiments of the invention ways groups may be implemented in separate physical arrays and/or in the same physical array, although the scope of the present invention is in no way limited in this respect.

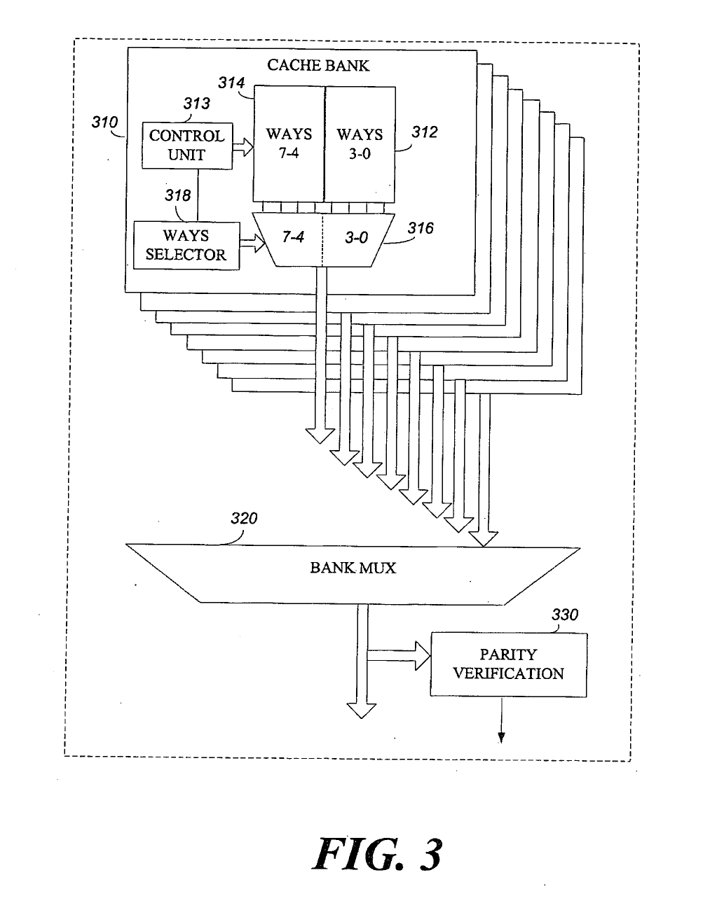

Turning to FIG. 3 an illustration of a block diagram of a read data path and parity calculation of a cache 200 according to an exemplary embodiment of the present invention is shown. According to this exemplary embodiment of the invention, cache 300 may include for example, at least a L1 cache. According to this example, the L1 cache may include a plurality of cache banks 310, multiplexer 320, and a parity verification block 330. According to some exemplary embodiments of the invention, cache banks 310 may include eight cache banks. The eight cache banks may include a similar architecture, including a ways group 312, a ways group 314, a control unit 313, a multiplexer 316 and a way selector 318.

According to this exemplary embodiment of the invention, a cache bank of cache banks 310 may include eight ways. A way may include eight bytes and one parity bit for each byte. In this exemplary embodiment of the invention, the ways may be arranged in two groups. For example, ways group 312 may include ways 0-3 and ways group 314 may include ways 4-7. In exemplary embodiments of the present invention, ways 4-7 are a replica of the data of ways 0-3. Multiplexer 316 may be able to select between the ways of ways groups 312, 314. Control unit 313 may include a control logic (not shown). The control logic may be able to select a way of ways 0-3 according to the way-hit indication in case of a normal operation and/or to select any way of ways 0-7 as determined by the control logic for special operations such as, for example line evictions, direct way addressing operations, or the like.

According to some embodiments of the present invention, error detection and/or error correction may be preformed according to the following example. Multiplexer 316 may be able to select at least one ways group to perform an error detection, if desired. According to this example, any write operation to way n of ways group 312 (e.g., ways 0-3) may write the same data to way n+4 of ways group 314 (e.g. ways 4-7). In addition, ways selector 318 may select ways group 312 by forcing ways group 314 controls to an invalid state, if desired.

Multiplexer 320 may select the cache bank according to address bits of, for example, a bank selector (not shown) operable coupled to multiplexer 320, if desired. Parity verification block 330 may perform a test for parity error in ways group 312. For example, parity verification block 330 may compute the parity for a byte of the selected way and bank (e.g., way n, cache bank m). Additionally or alternatively, parity verification block 330 may compare a computed parity bit with the parity bit of the verified byte. For example, a parity mismatch may be reported to a retiring logic in a reorder buffer (ROB) unit (not shown) causing a micro-exception. In case of parity error, a micro-event and a correction microcode assist hlow may be invoked by the micro exception.

According to some exemplary embodiments of the invention, error correction may be done by retrieving the data from the replica way in the other ways group (e.g. ways group 314) and replacing the erroneous data in the error-detected way of ways group 312, if desired. It should be understood that the method of detecting and correcting error may be applied to any array unit, for example, a Tag array or the like.

While certain features of the invention have been illustrated and described herein, many modifications, substitutions, changes, and equivalents will now occur to those skilled in the art. It is, therefore, to be understood that the appended claims are intended to cover all such modifications and changes as fall within the true spirit of the invention.

What is claimed is:

1. An method comprising:
replicating data of a first ways group into a second ways group;
detecting a soft error in a way of the first ways group; and
correcting the soft error by copying data of a way of the second ways group to an error detected way of the first ways group, wherein the way of the second ways group includes a correct data of the error detected way of the first ways group.

2. The method of claim 1, wherein detecting comprises:
detecting the soft error in a way by comparing an output of the first ways group to a copy of an equivalent output in the second ways group.

3. The method of claim 2, comprising:
performing a parity verification to the way of the second ways group.

4. The method of claim 1, wherein detecting comprises:
detecting the soft error in a way by performing a parity verification to one or more ways of the first ways group.

5. The method of claim 1, wherein correcting comprises:
invoking a correction micro-code assist flow to correct the soft error.

6. The method of claim 1, wherein correcting comprises:
invoking a hardware logic mechanism to correct the soft error.

7. The method of claim 1, wherein replicating comprises:
replicating the data of one or more ways of the first ways group to one or more ways of the second ways group, wherein the fist ways group is located in a cache bank different from that of the second ways group.

8. An apparatus comprising:
a cache comprising a plurality of cache banks, wherein a cache bank includes a first ways group and a second ways group, wherein the second ways group includes data which is a copy of data of the first ways group, and wherein the cache is capable of using data of both the first and second ways groups to detect and correct a soft error of a way of at least one ways group of the first and second ways groups.

9. The apparatus of claim 8, wherein the cache bank comprises:
a first multiplexer to output first data related to the first ways group;
a second multiplexer to output second data related to the second ways group; and
a third multiplexer to receive output data from the first and second multiplexers and to output selected data related to a selected ways group which is selected from the first and second ways groups.

10. The apparatus of claim 8, comprising:
a comparator capable of detecting the soft error in a way by comparing an output of the first ways group to a copy of a corresponding output in the second ways group.

11. The apparatus of claim 10, comprising:
a parity verification block to perform a parity verification to the data of the corresponding output of the second group.

12. The apparatus of claim 10, comprising:
an error detection control logic to receive a soft error indication from the comparator and to invoke a correction micro-code assist flow to correct the soft error.

13. The apparatus of claim 12, wherein the micro-code assist flow is able to correct the soft error in the way of the first ways group by copying data from an equivalent way of the second ways group to the way of the first ways group.

14. The apparatus of claim 10, comprising:
an error detection control logic to receive a soft error indication from the comparator and to invoke a hardware logic mechanism to correct the soft error.

15. The apparatus of claim 8, comprising:
a way selector to select a ways group from the first and second ways groups by controlling a multiplexer to route the selected ways group to a bank multiplexer.

16. The apparatus of claim 15, comprising:
a parity verification block to perform a parity verification to detect a soft error in a way of the selected ways group by performing a parity verification to one or more ways of the selected ways group.

17. The apparatus of claim 16, wherein the parity verification block is able to invoke a correction micro-code assist flow to correct the soft error.

18. The apparatus of claim 17, wherein the micro-code assist flow is able to correct the soft error in the way of the first ways group by copying data from an equivalent way of the second ways group to the way of the first ways group.

19. The apparatus of claim 16, wherein the parity verification block is able to invoke a correction hardware logic mechanism to correct the soft error.

20. The apparatus of claim 8, wherein the first ways groups and the second ways groups are located in different physical cache banks.

21. The apparatus of claim 8, wherein the cache includes a level one cache.

22. The apparatus of claim 8, wherein the cache includes an array.

23. A computer system comprising:
an addressing server having a cache comprising a plurality of cache banks, wherein a cache bank include a first ways group and a second ways group, wherein the second ways group includes data which is a copy of data of the first ways group, and the data of the first and second ways group are used for detecting and correcting a soft error of a way of at least one ways group of the first and second ways groups.

24. The computer system of claim 23, wherein the cache bank comprises:
a first multiplexer to output a first data related to the first ways group;
a second multiplexer to output a second data related to the second ways group; and
a third multiplexer to receive data from the first and second multiplexers and to output a selected data related to of a selected ways group which is selected from the first and second ways groups.

25. The computer system of claim 23, comprising:
a comparator capable of detecting the soft error in a way by comparing an output of the first ways group to a copy of a corresponding output in the second ways group.

26. The computer system of claim 25, comprising:
a parity verification block to perform a parity verification to the data of the corresponding output of the second group.

27. The computer system of claim 25, comprising:
an error detection control logic to receive a soft error indication from the comparator and to invoke a correction a micro-code assist flow to correct the soft error.

28. The computer system of claim 27, wherein the micro-code assist flow is able to correct the soft error in the way of the first ways group by copying data from an equivalent way of the second ways group to the way of the first ways group.

29. The computer system of claim 25, wherein the addressing server comprises:
an error detection control logic to receive a soft error indication from the comparator and to invoke a hardware logic mechanism to correct the soft error.

30. The computer system of claim 23, comprising:
a way selector to select a ways group from the first and second ways groups by controlling a multiplexer to route the selected ways group to a bank multiplexer.

31. The computer system of claim 25, comprising:
a parity verification block to perform a parity verification to detect a soft error in a way of the selected ways group by performing a parity verification to one or more ways of the selected ways group.

32. The computer system of claim 31, wherein the parity verification block is able to invoke a correction a micro-code assist flow to correct the soft error.

33. The computer system of claim 32, wherein the micro-code assist flow is able to correct the soft error in the way of the first ways group by copying data from an equivalent way of the second ways group to the way of the first ways group.

34. The computer system of claim 31, wherein the parity verification block is able to invoke a hardware logic mechanism to correct the soft error.
